(19) United States
(12) Patent Application Publication
(10) Pub. No.: US 2026/0223292 A1
(43) Pub. Date: Jul. 30, 2026

(54) SEMICONDUCTOR STORAGE DEVICE, AND SEMICONDUCTOR STORAGE DEVICE MANUFACTURING METHOD

(71) Applicant: Kioxia Corporation, Tokyo (JP)

(72) Inventors: Masamichi YOKOMIZO, Chigasaki Kanagawa (JP); Daigo SUZUKI, Kawasaki Kanagawa (JP); Yasuyuki OHYAMA, Yokohama Kanagawa (JP)

(21) Appl. No.: 19/318,291

(22) Filed: Sep. 3, 2025

(30) Foreign Application Priority Data
Jan. 29, 2025 (JP) 2025-012889

(51) Int. Cl. H05K 1/184

(52) U.S. Cl. CPC H05K 1/184; H05K 2201/10015; H05K 2201/10159

(57) ABSTRACT

A semiconductor storage device includes a substrate, a semiconductor memory provided on the substrate having a connecting portion, and an electronic part that has a main body that is disposed in the substrate, and a lead extending from the main body. A central axial line of the main body is aligned with a center of the substrate in a thickness direction of the substrate. The lead extends linearly and has a leading end that is fixed to the connecting portion and aligned with the connecting portion in a direction along which the lead extends from the main body.

### CROSS-REFERENCE TO RELATED APPLICATIONS

This application is based upon and claims the benefit of priority from Japanese Patent Application No. 2025-012889, filed January 29, 2025, the entire contents of which are incorporated herein by reference.

### FIELD

Embodiments described herein relate generally to a semiconductor storage device, and to a semiconductor storage device manufacturing method.

### BACKGROUND

A semiconductor storage device including a substrate having a through hole and an electronic part having a lead inserted into the through hole is already known.

### BRIEF DESCRIPTION OF THE DRAWINGS

FIG. 1 is a perspective view showing a semiconductor storage device of a first embodiment.

FIG. 2 is an exploded view of the semiconductor storage device of the first embodiment.

FIGS. 3A-3C illustrate a capacitor of the first embodiment.

FIG. 4 is a perspective view showing one portion of a substrate of the first embodiment.

FIG. 5 is a sectional view along an F5-F5 line of one portion of the substrate shown in FIG. 4.

FIGS. 6A-6C illustrate a positional relationship between the substrate and the capacitor of the first embodiment.

FIG. 7 is a sectional view along an F7-F7 line of the semiconductor storage device shown in FIG. 1.

FIG. 8 is an enlarged plan view showing a connecting portion of a substrate of a second embodiment.

FIG. 9 is an enlarged perspective view showing a conductive portion of the connecting portion of the second embodiment in a state separated from the substrate.

FIG. 10 is an enlarged perspective view showing a modification of the conductive portion of FIG. 9.

FIG. 11 is a perspective view of an axial capacitor.

### DETAILED DESCRIPTION

Embodiments provide a semiconductor storage such that a required level of processing technology and processing accuracy can be lowered.

In general, according to one embodiment, a semiconductor storage device includes a substrate having a connecting portion, a semiconductor memory provided on the substrate, and an electronic part that has a main body that is disposed in the substrate, and a lead extending from the main body. A central axial line of the main body is aligned with a center of the substrate in a thickness direction of the substrate. The lead extends linearly and has a leading end that is fixed to the connecting portion and aligned with the connecting portion in a direction along which the lead extends from the main body.

Hereafter, a semiconductor storage device of embodiments will be described, with reference to the drawings. In the following description, identical reference signs are assigned to configurations having identical or similar functions. Further, redundant descriptions of these configurations may be omitted. In the present application, "parallel", "perpendicular", and "the same" may include cases of being "approximately parallel", "approximately perpendicular", and "approximately the same" respectively. In the present application, "coincide" means that virtual projected images of two subjects on an imaginary plane coincide. That is, "coincide" is not limited to a case in which two subjects come into contact, and may also include a case in which two subjects do not come into contact (for example, a case in which a space or another member exists between two subjects). In the present application, "fixed" is not limited to a case in which two subjects are directly fixed, and may also include a case in which two subjects are fixed with another member interposed therebetween. In the present application, "connection" is not limited to a mechanical connection, and may also include an electrical connection. In addition, "connection" is not limited to a case of being connected directly to a subject, and may also include a case of being connected to a subject with another member interposed therebetween.

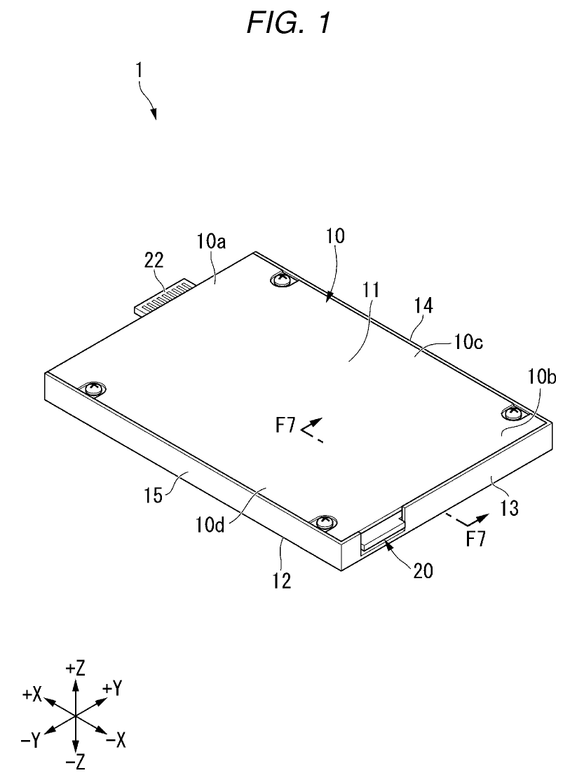

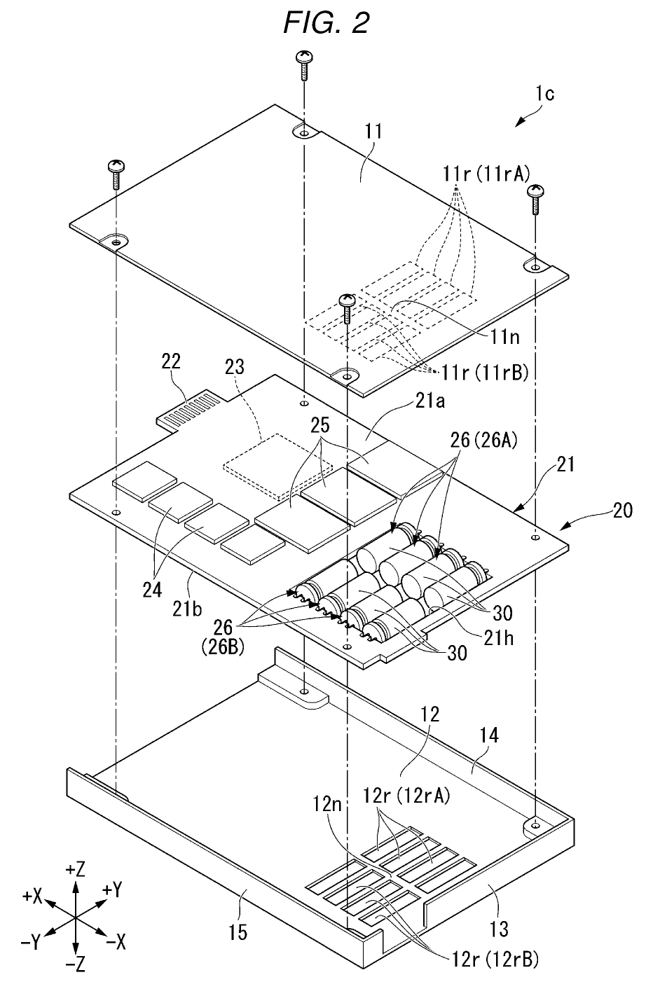

In the present application, a +X direction, a -X direction, a +Y direction, a -Y direction, a +Z direction, and a -Z direction are defined as follows. The +X direction, the -X direction, the +Y direction, and the -Y direction are directions parallel to a first face 21a (refer to FIG. 2) of a substrate 21 to be described hereafter. The +X direction is a direction from a second end portion 10b toward a first end portion 10a of a housing 10 to be described hereafter (refer to FIG. 1). The -X direction is a direction opposite to the +X direction. When not distinguishing between the two, the +X direction and the -X direction are called simply an "X direction". The +Y direction and the -Y direction are directions that intersect (for example, are perpendicular to) the X direction. The +Y direction is a direction from a fourth end portion 10d toward a third end portion 10c of the housing 10, to be described hereafter (refer to FIG. 1). The -Y direction is a direction opposite to the +Y direction. When not distinguishing between the two, the +Y direction and the -Y direction are called simply a "Y direction". The +Z direction and the -Z direction are directions that intersect (for example, are perpendicular to) the X direction and the Y direction, and are thickness directions of the substrate 21. The +Z direction is a direction from the substrate 21 toward a first main wall 11 of the housing 10 (refer to FIG. 2). The -Z direction is a direction opposite to the +Z direction. When not distinguishing between the two, the +Z direction and the -Z direction are called simply a "Z direction". The +Z direction side is one example of a "first side". The -Z direction side is one example of a "second side".

Hereafter, a semiconductor storage device of the embodiments will be described, with reference to the drawings.

### First Embodiment

Referring to FIGS. 1 to 7, a semiconductor storage device 1 of a first embodiment will be described. The semiconductor storage device 1 is a storage device such as a solid-state drive (SSD). The semiconductor storage device 1 is attached to a host device, and is used as a storage device of the host device. The host device is a personal computer, a mobile device, a video recorder, a vehicle-mounted device, or the like, but is not limited to these examples.

FIG. 1 is a perspective view showing the semiconductor storage device 1. The semiconductor storage device 1 has, for example, the housing 10 and a substrate unit 20.

The housing 10 is a member that forms an outer shell of the semiconductor storage device 1. The housing 10 is of, for example, a flattened rectangular box form. The housing 10 has the first end portion 10a and the second end portion 10b as a pair of end portions separated in a longitudinal direction (the X direction) of the housing 10. The first end portion 10a has a connection connector 22 of the substrate unit 20, to be described hereafter, in an aperture (not shown) exposed in an external portion of the housing 10. The housing 10 has the third end portion 10c and the fourth end portion 10d as a pair of end portions separated in a lateral direction (the Y direction) of the housing 10.

The housing 10 has, for example, the first main wall 11, a second main wall 12, a first side wall 13, a second side wall 14, and a third side wall 15. The first main wall 11 is a wall extending in the X direction and the Y direction. The first main wall 11 is positioned on the +Z direction side with respect to the substrate unit 20. The first main wall 11 faces the substrate 21, to be described hereafter, from the +Z direction side. The first main wall 11 is one example of a "first wall". The second main wall 12 is a wall extending in the X direction and the Y direction. The second main wall 12 is positioned on the -Z direction side with respect to the substrate unit 20. The second main wall 12 faces the substrate 21 from the -Z direction side. The second main wall 12 is one example of a "second wall". Each of the first side wall 13, the second side wall 14, and the third side wall 15 is a wall extending in the Z direction between an end portion of the first main wall 11 and an end portion of the second main wall 12. The first side wall 13 is positioned at an end portion on the -X direction side of the housing 10. The second side wall 14 is positioned at an end portion on the +Y direction side of the housing 10. The third side wall 15 is positioned at an end portion on the -Y direction side of the housing 10.

Hereafter, the substrate unit 20 will be described. FIG. 2 is an exploded view of the semiconductor storage device 1. The substrate unit 20 is housed in the housing 10. The substrate unit 20 has, for example, the substrate 21, the connection connector 22, a controller 23, a plurality of dynamic random-access memories (DRAMs) 24, a plurality of NAND flash memories 25 (hereafter called "NAND 25"), and a plurality of capacitors (storage parts) 26. In the present embodiment, each capacitor 26 is a capacitor of, for example, a cylindrical form. The plurality of capacitors 26 include a group of a plurality of capacitors 26A, which are arranged in parallel, and a group of a plurality of capacitors 26B, which are also arranged in parallel.

The substrate 21 is a plate member that extends in the X direction and the Y direction. The substrate 21 is a printed circuit board, and includes an insulating base, and a wiring pattern provided on the insulating base. The substrate 21 has the first face 21a, and a second face 21b positioned on a side opposite to that of the first face 21a. The first face 21a extends in the X direction and the Y direction. The first face 21a is oriented in the +Z direction. The second face 21b extends in the X direction and the Y direction. The second face 21b is oriented in the -Z direction.

The substrate 21 has an aperture 21h. The aperture 21h is of, for example, a rectangular form having a longitudinal direction in the Y direction. The aperture 21h is a through hole that penetrates the substrate 21 in the Z direction. The aperture 21h is one example of a "space portion". A part main body (a main body) 30 of the capacitor 26, to be described hereafter, is disposed in the aperture 21h. In the present embodiment, the aperture 21h has a size such that the part main bodies 30 of the plurality of capacitors 26 that are arranged in the Y direction can be housed therein.

The connection connector 22 is a connecting portion that can be connected to a connector of a host device. The connection connector 22 is also called an edge connector. The connection connector 22 has a plurality of metal terminals that can be connected to a connector of a host device. The connection connector 22 is provided in an end portion on the +X direction side of the substrate 21.

The controller 23 is a part that controls the semiconductor storage device 1. The controller 23 is, for example, a semiconductor package including a system on a chip (SoC) in which a host interface circuit with respect to a host device, a control circuit that controls the plurality of DRAMs 24, a control circuit that controls the plurality of NANDs 25, and the like, are integrated in one semiconductor chip. The controller 23 is provided on, for example, the second face 21b of the substrate 21.

The DRAM 24 is a semiconductor package including a volatile semiconductor memory chip. The DRAM 24 is a data buffer in which write target data received from a host device, read target data read from the NAND 25, or the like, are temporarily stored. The DRAM 24 is provided on, for example, the first face 21a of the substrate 21. Alternatively, the DRAM 24 may be provided as part of the controller 23.

The NAND 25 is a semiconductor package including a non-volatile semiconductor memory chip. The NAND 25 is, for example, provided on the first face 21a and the second face 21b of the substrate 21. The plurality of NANDs 25 are disposed arranged in the X direction and the Y direction. The NAND 25 is one example of a "semiconductor memory". Hereafter, the NAND 25 may be called the semiconductor memory 25. A "semiconductor memory" in the present application, not being limited to the NAND 25, may be another kind of semiconductor memory such as a NOR memory, a magnetoresistive random-access memory (MRAM), or a resistive random-access memory.

The capacitor 26 is one of the parts electrically connected to the substrate 21. The capacitor 26 has, for example, a power supply backup function with an object of data protection when an unexpected power interruption occurs. In the present embodiment, the capacitor 26 supplies power for a certain time to the controller 23, the plurality of DRAMs 24, and the plurality of NANDs 25 when a supply of power from a host device is unexpectedly interrupted. The capacitor 26 is, for example, an electrolytic capacitor. Furthermore, the capacitor 26 is, for example, an aluminum electrolytic capacitor. It should be noted that the capacitor 26, not being limited to the aforementioned example, also includes a dipped type, a box type, and an axial capacitor.

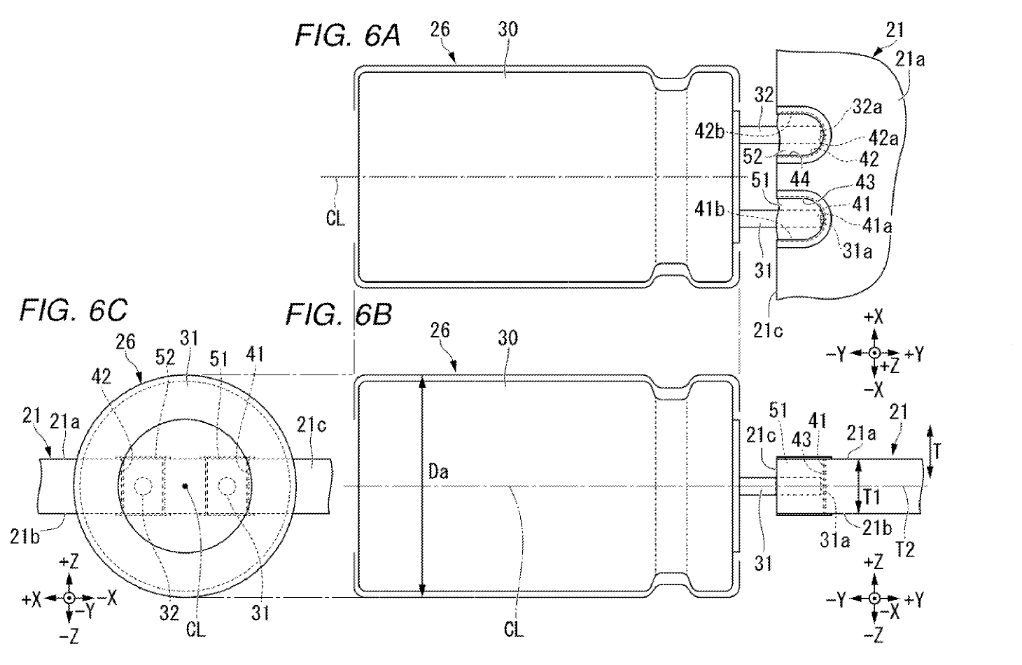

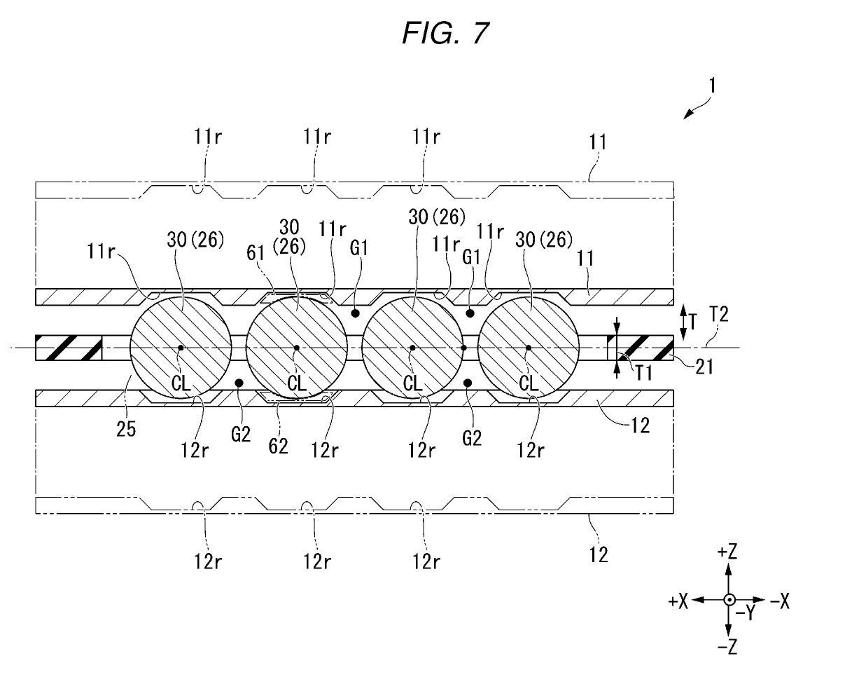

FIG. 11 shows an axial capacitor 26'. The capacitor 26' is such that leads 31 and 32 each extend from one end in an axial direction of the part main body 30, which is of, for example, a cylindrical form. The capacitor 26' is disposed in such a way that a central axial line of the part main body 30 is housed within a thickness T1 of the substrate 21 in a thickness direction T of the substrate 21, in the same way as a disposition and a mounting structure for the capacitor 26, to be described hereafter (refer to FIGS. 6 and 7). When the extended leading ends of the leads 31 and 32 of capacitors 26 are arranged to oppose a connecting portion of the substrate 21 in directions in which the leads 31 and 32 extend from the part main body 30, the leads 31 and 32 are fixed to the connecting portion. The capacitors 26 and 26' are examples of "electronic parts".

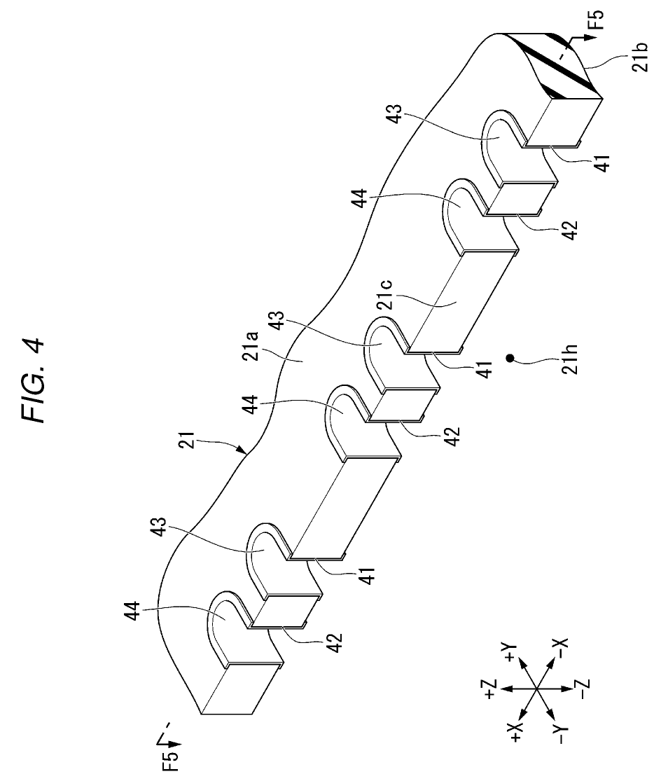

Of the plurality of capacitors 26, a plurality of capacitors 26A are disposed on the +Y direction side with respect to a plurality of capacitors 26B. The plurality of capacitors 26A are arranged in the X direction. The first lead 31 and the second lead 32 of the capacitor 26A protrude to the +Y direction side from the part main body 30 of the capacitor 26A. The first lead 31 and the second lead 32 of the capacitor 26A are inserted into a first recess 41 and a second recess 42 provided on the +Y direction side of the aperture 21h (refer to FIG. 4).

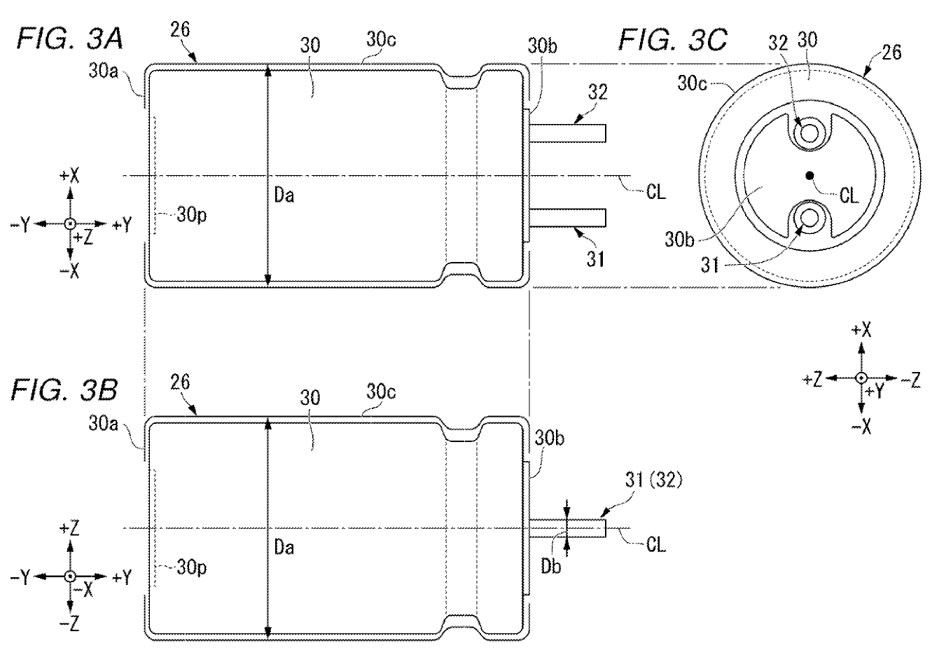

Meanwhile, the plurality of capacitors 26B are disposed between the plurality of capacitors 26A and the third side wall 15 of the housing 10 in the Y direction. The plurality of capacitors 26B are arranged in the X direction. The first lead 31 and the second lead 32 of the capacitor 26B protrude to the -Y direction side from the part main body 30 of the capacitor 26B. The first lead 31 and the second lead 32 of the capacitor 26B are inserted into the first recess 41 and the second recess 42 provided on the -Y direction side of the aperture 21h (refer to FIG. 4). A gap of a distance (for example, 2mm) necessary for a pressure valve 30p of the capacitors 26 (see FIGS. 3A and 3B) to open may be provided between the capacitor 26A and the capacitor 26B arranged in the Y direction.

A plurality of recesses 11r provided in the first main wall 11 include a plurality of recesses 11rA and a plurality of recesses 11rB. The plurality of recesses 11rA are disposed in positions corresponding one-to-one with the plurality of capacitors 26A. When seen from the Z direction, the recess 11rA coincides with the part main body 30 of the capacitor 26A. One portion of the part main body 30 of the capacitor 26A is disposed on an inner side of the recess 11rA, and is positioned farther to the +Z direction side than one portion (for example, an end on the -Z direction side) of the first main wall 11.

The plurality of recesses 11rB are disposed in positions corresponding one-to-one with the plurality of capacitors 26B. When seen from the Z direction, the recess 11rB coincides with the part main body 30 of the capacitor 26B. One portion of the part main body 30 of the capacitor 26B is disposed on an inner side of the recess 11rB, and is positioned farther to the +Z direction side than one portion (for example, an end on the -Z direction side) of the first main wall 11.

A plurality of recesses 12r provided in the second main wall 12 include a plurality of recesses 12rA and a plurality of recesses 12rB. The plurality of recesses 12rA are disposed in positions corresponding one-to-one with the plurality of capacitors 26A. When seen from the Z direction, the recess 12rA coincides with the part main body 30 of the capacitor 26A. One portion of the part main body 30 of the capacitor 26A is disposed on an inner side of the recess 12rA, and is positioned farther to the -Z direction side than one portion (for example, an end on the +Z direction side) of the second main wall 12.

The plurality of recesses 12rB are disposed in positions corresponding one-to-one with the plurality of capacitors 26B. When seen from the Z direction, the recess 12rB coincides with the part main body 30 of the capacitor 26B. One portion of the part main body 30 of the capacitor 26B is disposed on an inner side of the recess 12rB, and is positioned farther to the -Z direction side than one portion (for example, an end on the +Z direction side) of the second main wall 12.

The first main wall 11 has a thick portion 11n between the recess 11rA and the recess 11rB. As is evident from FIG. 7, the thick portion 11n is a portion of the first main wall 11 that is thick in comparison with a portion in which the recess 11rA or the recess 11rB is provided. The thick portion 11n, for example, extends in the X direction maintaining a certain thickness. A beam extending in the X direction is formed by the thick portion 11n between the recess 11rA and the recess 11rB.

In the same way, the second main wall 12 has a thick portion 12n between the recess 12rA and the recess 12rB. The thick portion 12n is a portion of the second main wall 12 that is thick in comparison with a portion in which the recess 12rA or the recess 12rB is provided. The thick portion 12n, for example, extends in the X direction maintaining a certain thickness. A beam extending in the X direction is formed by the thick portion 12n between the recess 12rA and the recess 12rB.

FIGS. 3A-3C illustrate the capacitor 26. The capacitor 26 has, for example, the part main body 30, the first lead 31, and the second lead 32.

The part main body 30 is a portion that has a main function of an electronic part. For example, the part main body 30 of the capacitor 26 is a part that accumulates a charge in response to a direct current voltage being applied across the terminals thereof. The part main body 30 includes, for example, metal that forms an electrode, a dielectric, and an electrolyte. The part main body 30 is of a cylindrical form. A diameter Da of the part main body 30 may be greater than the thickness T1 in the Z direction of the substrate 21 (refer to FIG. 6). The part main body 30 includes, for example, a first end face 30a, a second end face 30b, and a peripheral face 30c.

The first end face 30a is a side face positioned on a side opposite to that of the first lead 31 and the second lead 32. The first end face 30a is circular. The pressure valve (a safety valve) 30p is provided on the first end face 30a. The pressure valve 30p is opened when an internal pressure of the part main body 30 rises to or above a predetermined reference value, such as when an abnormality occurs, and discharges gas inside the part main body 30 to an exterior of the part main body 30. It should be noted that the pressure valve 30p is not always needed.

The second end face 30b is positioned on a side opposite to that of the first end face 30a. The second end face 30b is circular. The first lead 31 and the second lead 32 protrude from the second end face 30b. The peripheral face 30c extends in a direction that intersects (for example, is perpendicular to) the first end face 30a and the second end face 30b, and extends from the first end face 30a to the second end face 30b. The peripheral face 30c is of an annular form.

The first lead 31 is a first terminal used for electrical connection. The first lead 31 protrudes from the second end face 30b of the part main body 30. The first lead 31 protrudes in a direction that intersects (for example, is perpendicular to) the second end face 30b. The first lead 31 extends linearly in a direction away from the part main body 30. The first lead 31 is of a cylindrical form having a diameter Db. The first lead 31 extends parallel to the axial direction of the part main body 30. The first lead 31 has a leading end face 31a (see FIG. 6A) that opposes an inner cover portion 83 of a first conductive portion 43, to be described hereafter, in the direction of extension of the first lead 31. Hereafter, the leading end face 31a may be called the extended leading end 31a.

The second lead 32 is a second terminal used for electrical connection. The second lead 32 protrudes from the second end face 30b of the part main body 30. The second lead 32 protrudes in a direction that intersects (for example, is perpendicular to) the second end face 30b. The second lead 32 extends linearly in a direction away from the part main body 30. The second lead 32 is of a cylindrical form having a diameter Db. The second lead 32 extends parallel to the axial direction of the part main body 30. The second lead 32 has a leading end face 32a (see FIG. 6A) that opposes the inner cover portion 83 of a second conductive portion 44, to be described hereafter, in the direction of extension of the second lead 32. Hereafter, the leading end face 32a may be called the extended leading end 32a.

Hereafter, a mounting structure for the capacitor 26 will be described. Also, a structure of the substrate 21 relating to the mounting structure for the capacitor 26 will be described.

FIG. 4 is a perspective view showing one portion of the substrate 21 neighboring the aperture 21h. The substrate 21 has a third face 21c. The third face 21c extends in the Z direction from the first face 21a to the second face 21b. The third face 21c is an end face that has a thickness corresponding to a thickness of the substrate 21. In the present embodiment, the third face 21c is an end face that neighbors the aperture 21h, and defines an edge of the aperture 21h.

In the present embodiment, the substrate 21 has the first recess 41, the second recess 42, the first conductive portion 43, and the second conductive portion 44 as one portion of the mounting structure for the capacitor 26.

The first recess 41 and the second recess 42 are provided in the third face 21c. The first recess 41 and the second recess 42 are provided on one of the edges of the aperture 21h, that is positioned on the +Y direction side with respect to the aperture 21h. The first recess 41 and the second recess 42 are disposed in differing positions in the X direction. Each of the first recess 41 and the second recess 42 is recessed in the +Y direction with respect to the third face 21c. The first recess 41 and the second recess 42 extend in the Z direction. For example, the first recess 41 and the second recess 42 penetrate the substrate 21 in the Z direction, and extend from the first face 21a to the second face 21b of the substrate 21. In the present embodiment, an interior of the first recess 41 and an interior of the second recess 42 neighbor the aperture 21h. The interior of the first recess 41 and the interior of the second recess 42 communicate with the aperture 21h.

The first conductive portion 43 is provided on an inner face of the first recess 41. The first conductive portion 43 is, for example, a metal layer (for example, a plating layer) formed along the inner face of the first recess 41. The first conductive portion 43 is, for example, a metal layer having a thickness of 0.05mm. In addition to the inner face of the first recess 41, the first conductive portion 43 may also be provided on at least one of the first face 21a and the second face 21b of the substrate 21. The first conductive portion 43 is an end face through hole, and is connected to a wiring pattern of the substrate 21.

The second conductive portion 44 is provided on an inner face of the second recess 42. The second conductive portion 44 is, for example, a metal layer (for example, a plating layer) formed along the inner face of the second recess 42. The second conductive portion 44 is, for example, a metal layer having a thickness of 0.05mm. In addition to the inner face of the second recess 42, the second conductive portion 44 may also be provided on at least one of the first face 21a and the second face 21b of the substrate 21. The second conductive portion 44 is an end face through hole, and is connected to a wiring pattern of the substrate 21 and electrically isolated from the first conductive portion 43.

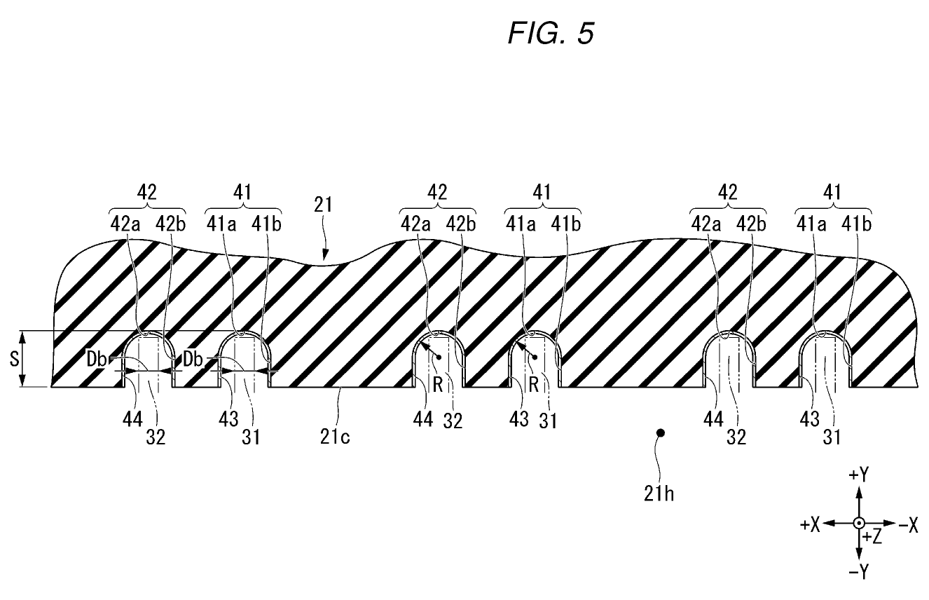

FIG. 5 is a sectional view along an F5-F5 line of one portion of the substrate 21 shown in FIG. 4. In the present embodiment, the first recess 41 has an arc portion 41a and a linear portion 41b. The arc portion 41a is positioned at a back portion of the first recess 41. The arc portion 41a is, for example, recessed in an arc form in a direction away from the aperture 21h when seen from the Z direction. The arc portion 41a is of, for example, a semi-circular form when seen from the Z direction. The linear portion 41b extends in a linear form in the -Y direction from each of two ends in the X direction of the arc portion 41a. The linear portion 41b extends from the arc portion 41a to the third face 21c. The first conductive portion 43 is provided in both the arc portion 41a and the linear portion 41b.

The diameter Db of the first lead 31 is, for example, 0.5mm (with a tolerance of ± 0.05mm). A radius of curvature R of the arc portion 41a is, for example, 0.5mm. A length in the Y direction of the linear portion 41b is, for example, 0.8mm. In the present embodiment, a depth S in the Y direction of the first recess 41 is greater than the diameter Db of the first lead 31. For example, the depth S in the Y direction of the first recess 41 is two times or more greater than the diameter Db of the first lead 31.

In the same way, the second recess 42 has an arc portion 42a and a linear portion 42b. The arc portion 42a is positioned at a back portion of the second recess 42. The arc portion 42a is, for example, recessed in an arc form in a direction away from the aperture 21h when seen from the Z direction. The arc portion 42a is of, for example, a semi-circular form when seen from the Z direction. The linear portion 42b extends in a linear form in the -Y direction from each of two ends in the X direction of the arc portion 42a. The linear portion 42b extends from the arc portion 42a to the third face 21c. The second conductive portion 44 is provided in both the arc portion 42a and the linear portion 42b.

The diameter Db of the second lead 32 is, for example, 0.5mm (with a tolerance of ± 0.05mm). The radius of curvature R of the arc portion 42a is, for example, 0.5mm. A length in the Y direction of the linear portion 42b is, for example, 0.8mm. In the present embodiment, the depth S in the Y direction of the second recess 42 is greater than the diameter Db of the second lead 32. For example, the depth S in the Y direction of the second recess 42 is two times or more greater than the diameter Db of the second lead 32.

In FIGS. 4 and 5 described above, the portion of the substrate 21 that faces the recess 21h and the capacitors 26A in the -Y direction is illustrated. Although not shown, the substrate 21 has another portion, which is a mirror image of the portion illustrated in FIGS. 4 and 5, that faces the recess 21h and the capacitors 26B in the +Y direction.

Hereafter, a positional relationship between the substrate 21 and the capacitor 26 will be described. FIGS. 6A-6C illustrate the positional relationship between the substrate 21 and the capacitor 26. As heretofore described, the part main body 30 of the capacitor 26 is disposed in the aperture 21h. The first end face 30a of the part main body 30 is disposed in the aperture 21h so that at least a distance (for example, 2 mm) necessary for the pressure valve 30p to open between two first end faces 30a of capacitor 26 aligned in the Y direction (refer to FIG. 2).

As shown in FIGS. 6A and 6B, the part main body 30 overlaps with the third face 21c of the substrate 21 when seen in the Y direction. In the present embodiment, a central axial line CL following the axial direction of the cylindrical part main body 30 overlaps with the third face 21c of the substrate 21 when seen in the Y direction. The central axial line CL of the part main body 30 is aligned with a center of the substrate along the thickness T1 thereof in the Z direction (the thickness direction T) when seen in the Y direction. For example, the central axial line CL of the part main body 30 is aligned with a central face line T2 in the Z direction (the thickness direction T) of the substrate 21 when seen in the Y direction.

The first lead 31 protrudes from the part main body 30 toward the first recess 41. A leading end of the first lead 31 is positioned on an inner side of the first recess 41. The first lead 31 is fixed to the first conductive portion 43 in a state in which at least one portion overlaps with the first recess 41 when seen from the Y direction. The first lead 31 is connected to the first conductive portion 43, and is electrically connected to a wiring pattern of the substrate 21 via the first conductive portion 43. The first conductive portion 43 is one example of a "connecting portion". Hereafter, the first conductive portion 43 may be called the connecting portion 43.

In the present embodiment, a conductive first joint portion 51 is provided in the interior of the first recess 41. The first joint portion 51 is, for example, a solder. In the present embodiment, the first lead 31 is electrically connected and mechanically fixed to the first conductive portion 43 through the first joint portion 51. In the present embodiment, the interior of the first recess 41 is filled with the first joint portion 51.

In the same way, the second lead 32 protrudes from the part main body 30 toward the second recess 42. A leading end of the second lead 32 is positioned on an inner side of the second recess 42. The second lead 32 is fixed to the second conductive portion 44 in a state in which at least one portion overlaps with the second recess 42 when seen from the Y direction. The second lead 32 is connected to the second conductive portion 44, and is electrically connected to a wiring pattern of the substrate 21 via the second conductive portion 44. The second conductive portion 44 is one example of a "connecting portion". Hereafter, the second conductive portion 44 may be called the connecting portion 44.

In the present embodiment, a conductive second joint portion 52 is provided in the interior of the second recess 42. The second joint portion 52 is, for example, a solder. In the present embodiment, the second lead 32 is electrically connected and mechanically fixed to the second conductive portion 44 with the second joint portion 52. In the present embodiment, the interior of the second recess 42 is filled with the second joint portion 52.

Hereafter, a structure of the housing 10 will be described by referring to FIG. 7, which is a sectional view along an F7-F7 line of the semiconductor storage device 1 shown in FIG. 1. In the present embodiment, the first main wall 11 of the housing 10 has the plurality of recesses 11r. The plurality of recesses 11r are disposed in positions corresponding one-to-one with the part main bodies 30 of the plurality of capacitors 26. When seen from the Z direction, the recess 11r coincides with the part main body 30 of the capacitor 26. The recess 11r is recessed to the +Z direction side, which is a direction away from the capacitor 26. One portion of the part main body 30 of the capacitor 26 is disposed on the inner side of the recess 11r, and is positioned farther to the +Z direction side than one portion (for example, an end on the -Z direction side) of the first main wall 11.

The second main wall 12 of the housing 10 has the plurality of recesses 12r. The plurality of recesses 12r are disposed in positions corresponding one-to-one with the part main bodies 30 of the plurality of capacitors 26. When seen from the Z direction, the recess 12r coincides with the part main body 30 of the capacitor 26. The recess 11r is recessed to the -Z direction side, which is a direction away from the capacitor 26. One portion of the part main body 30 of the capacitor 26 is disposed on the inner side of the recess 12r, and is positioned farther to the -Z direction side than one portion (for example, an end on the +Z direction side) of the second main wall 12. The recess 12r of the second main wall 12 has, for example, a form the same as that of the recess 11r of the first main wall 11. When seen from the Z direction, the recess 12r of the second main wall 12 coincides with the recess 11r of the first main wall 11.

A first buffer material 61 may be disposed between the recess 11r and the part main body 30 of the capacitor 26. The first buffer material 61 is made of, for example, a synthetic resin having flexibility, and has a high elasticity in comparison with the first main wall 11. The first buffer material 61 is, for example, sandwiched between the recess 11r and the part main body 30 of the capacitor 26. The first buffer material 61 restricts an impact applied to the first main wall 11 from an exterior of the housing 10 from being transmitted unchanged to the part main body 30 of the capacitor 26.

A second buffer material 62 may be disposed between the recess 12r and the part main body 30 of the capacitor 26. The second buffer material 62 is made of, for example, a synthetic resin having flexibility, and has a high elasticity in comparison with the second main wall 12. The second buffer material 62 is, for example, sandwiched between the recess 12r and the part main body 30 of the capacitor 26. The second buffer material 62 restricts an impact applied to the second main wall 12 from the exterior of the housing 10 from being transmitted unchanged to the part main body 30 of the capacitor 26.

As shown in FIG. 7, the first main wall 11 need not have the recess 11r in positions coinciding with the DRAM 24 and the NAND 25 in the Z direction. The first main wall 11 is separated from the DRAM 24 and the NAND 25. A first space G1 exists between the first main wall 11 and the DRAM 24 and NAND 25.

The second main wall 12 need not have the recess 12r in positions coinciding with the controller 23 and the NAND 25 in the Z direction. The second main wall 12 is separated from the controller 23 and the NAND 25. A second space G2 exists between the second main wall 12 and the controller 23 and NAND 25.

Hereafter, a method of manufacturing the semiconductor storage device 1 of the present embodiment will be described. The semiconductor storage device 1 includes at least the substrate 21, the semiconductor memory 25 provided on the substrate 21, and an electronic part (the capacitor 26) that has the part main body 30, whose external form has the central axial line CL, and the leads 31 and 32 extending from the part main body 30, and is such that the leads 31 and 32 are connected to the connecting portions 43 and 44 of the substrate 21.

In a first process, the capacitor 26 is disposed in such a way that the central axial line CL of the part main body 30 is aligned with a center of the substrate 21 in the thickness direction T of the substrate 21 (refer to FIG. 7). In a second process, the extended leading ends 31a and 32a of the leads 31 and 32 are caused to oppose the connecting portions 43 and 44 in the directions in which the leads 31 and 32 extend from the part main body 30 (refer to FIG. 6). In a third process, the leads 31 and 32 are fixed to the connecting portions 43 and 44 in the state in which the extended leading ends 31a and 32a are caused to oppose the connecting portions 43 and 44. As a result of these processes, the substrate 21 and the capacitor 26 are electrically connected.

Hereafter, advantages when the semiconductor storage device 1 of the present embodiment is used will be described.

In the present embodiment, the capacitor 26 is disposed in such a way that the central axial line CL of the part main body 30 is aligned with a center of the substrate 21 in the thickness direction T of the substrate 21. Further, the leads 31 and 32 are fixed to the connecting portions 43 and 44 in a state in which the extended leading ends 31a and 32a of the leads 31 and 32 are caused to oppose the connecting portions 43 and 44 in directions in which the leads 31 and 32 extend from the part main body 30. In other words, the extended leading ends 31a and 32a engage the connecting portions 43 and 44 in the direction along which the leads 31 and 32 extend from the part main body 30.

Because the leads 31 and 32 are fixed to the connecting portions 43 and 44 in a state in which the extended leading ends 31a and 32a of the leads 31 and 32 are caused to oppose the connecting portions 43 and 44, a process of bending the leads 31 and 32, and the like, is unnecessary, and manufacture of the capacitor 26, and by extension the semiconductor storage device 1, can be simplified. Furthermore, as the leads 31 and 32 are fixed to the connecting portions 43 and 44 without being bent, an inclination of the capacitor 26 caused by a variation in bending of the leads 31 and 32 do not occur. Consequently, a required level of processing technology and processing accuracy of the semiconductor storage device 1 can be lowered.

In the present embodiment, the capacitor 26 is a storage part having a cylindrical external form. According to this kind of configuration, the cylindrical capacitor 26 is disposed in such a way that the central axial line CL is aligned with a center of the substrate 21 in the thickness direction T of the substrate 21. As a result, the thickness of the semiconductor storage device 1 can be made small.

In the present embodiment, the leads 31 and 32 extend in the axial direction from an end face in the axial direction along the central axial line CL of the part main body 30 of the capacitor 26. Because the extended leading ends 31a and 32a of the leads 31 and 32 extending in the axial direction from the part main body 30 of the capacitor 26 are fixed to the connecting portions 43 and 44 of the substrate 21, a process of bending the leads 31 and 32 is unnecessary, and manufacture can be simplified.

In the present embodiment, the leads 31 and 32 are the pair of leads 31 and 32 that extend in parallel from an end face of the part main body 30. According to this kind of configuration, the plurality of leads 31 and 32 are fixed to the substrate 21 with no need for a bending process, As a result, manufacture is simplified, and inclination and deviation of the capacitor 26 can be prevented.

In the present embodiment, the connecting portions 43 and 44 are end face through holes provided in the recesses 41 and 42 formed by cutting out an edge portion of the aperture 21h of the substrate 21. With this configuration, it is possible to achieve a more streamlined structure by utilizing the end face through holes of the substrate 21 as the connecting portions 43 and 44 for the leads 31 and 32 of the capacitor 26.

Also, an end face through hole may be provided in a recess cut out from an outer peripheral portion of the substrate 21.

### Second Embodiment

Hereafter, a second embodiment will be described. The present embodiment differs from the first embodiment in that an anchor 82 formed of a laser via hole (LVH) is provided on a front face side and a back face side of the substrate 21 in an end face through hole. As other configurations described below are the same as configurations of the first embodiment, a detailed description will be omitted.

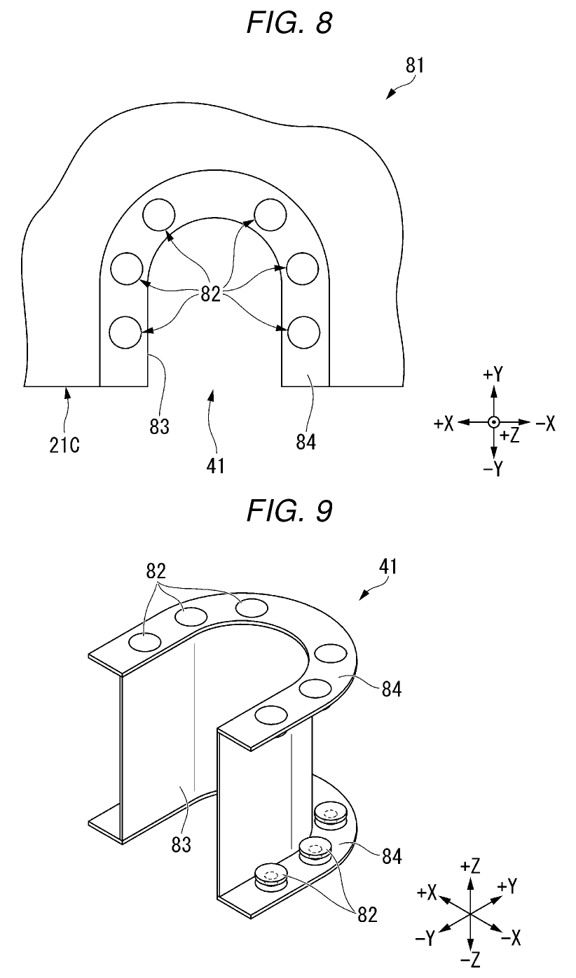

FIG. 8 is an enlarged top view showing an end face through hole of a substrate 81 of the present embodiment. FIG. 9 is an enlarged perspective view showing the first conductive portion 43 of the end face through hole of the substrate 81 in a state separated from the substrate 81. In the present embodiment, the substrate 81 is such that, in addition to the configuration of the substrate 21 described in the first embodiment, a plurality of the anchor 82 are provided on a front face side and a back face side of a region in which the first conductive portion 43 is provided. Note that the second conductive portion 44 has the same structure as the first conductive portion 43.

The first conductive portion 43 includes the inner cover portion 83 and a pair of flange portions 84. The inner cover portion 83 covers the inner side of the recess 41 of an edge portion of the substrate 81. The pair of flange portions 84 are each connected one face (a front face and a back face) of the inner cover portion 83 in the thickness direction T of the substrate 81, and extend along each of the front face and the back face of the substrate 81. The front face is either the first or the second face, while the back face is the other one. In the present embodiment, the anchor 82, which is fitted to the substrate 81 and fixes the first conductive portion 43 to the substrate 81, is provided in both of the pair of flange portions 84, but a configuration where the anchor 82 is provided in just one of the pair of flange portions 84 may also be adopted.

According to this kind of configuration, fixing of an end face through hole is strengthened by the anchor 82, and a falling out of an end face through hole when fixing a lead or conducting a repair can be suppressed.

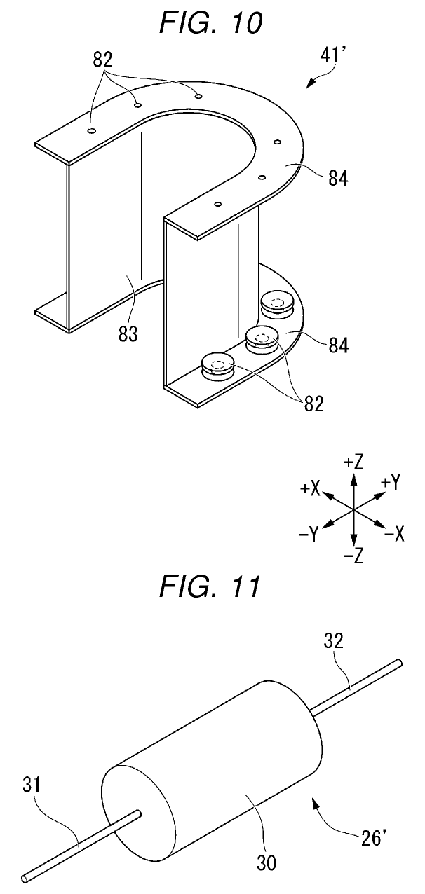

FIG. 10 is an enlarged perspective view showing a modification (a first conductive portion 43') of the first conductive portion 43 of FIG. 9. The first conductive portion 43 of FIG. 9 is an example in which there is no laser via recess, while the first conductive portion 43' of FIG. 10 is an example in which there is a laser via recess.

Although not shown, a plurality of the anchor 82 are also provided in the second conductive portion 44 of an end face through hole of the second recess 42, in the same way as in the first conductive portion 43 of the end face through hole of the first recess 41.

A semiconductor storage device of a configuration such that the anchor 82 is not disposed in the first conductive portion 43 and the second conductive portion 44 of an end face through hole will be considered as a comparative example. The comparative example is such that when a force pulling out to the outer peripheral side acts on an end face through hole provided in the recesses 41 and 42 opened on an outer peripheral side of the substrate 21, there is concern that the end face through hole will fall out from the recesses 41 and 42. In particular, when soldering, the end face through hole is attached to the substrate 21 at a temperature (approximately 350°) higher than that of a base material Tg (a glass transition temperature, approximately 150°) of the substrate 21. Because of this, the base material of the substrate 21 softens, and there is concern that with only an anchoring strength of a roughened copper foil surface, a force pulling out to the outer peripheral side will act when the solder aggregates, and the end face through hole will be pulled out from the recesses 41 and 42. Furthermore, when there is a need to repair a capacitor due to a positional deviation or damage to the capacitor, a high-temperature soldering iron is brought into contact with the solder, thereby removing the solder by causing the solder to aggregate. Because of this, there is concern that the end face through hole will fall out or peel off.

In contrast to the comparative example, the second embodiment is such that a plurality of the anchor 82 are disposed in the first conductive portion 43 and the second conductive portion 44 of the end face through hole, because of which an interior of the substrate 81 and the end face through hole can be structurally fitted together. Consequently, the end face through hole can be restricted from peeling off from the substrate 81, and a strength of connection between the capacitor 26 and the substrate 81 can be increased.

Some embodiments are described above. It should be noted that the embodiments are not limited to the heretofore described examples. For example, the heretofore described embodiments may be realized by being combined with each other.

In the heretofore described embodiments, the first recess 41 and the second recess 42 are recesses that penetrate the substrate 21 in the Z direction. However, the first recess 41 and the second recess 42, not being limited to the aforementioned example, may be recesses provided in only one surface of the substrate 21 (that is, recesses that do not penetrate the substrate 21 in the Z direction).

According to at least one of the heretofore described embodiments, a semiconductor storage device includes a substrate, a semiconductor memory provided on the substrate, and an electronic part that has a main body, whose external form has a central axial line, and a lead extending from the main body, and is such that the lead is connected to a connecting portion of the substrate. The electronic part is disposed in such a way that the central axial line of the main body is housed within a thickness of the substrate in a thickness direction of the substrate. The lead is fixed to the connecting portion in a state in which an extended leading end of the lead is caused to oppose the connecting portion in a direction in which the lead extends from the main body. According to this kind of configuration, a required level of processing technology and processing accuracy of the semiconductor storage device can be lowered.

In the embodiments, a capacitor is disposed in such a way that a central axial line of the main body is aligned with a center of the substrate in a thickness direction of the substrate. Further, the lead is fixed to the connecting portion in a state in which an extended leading end of the lead is caused to oppose the connecting portion in a direction in which the lead extends from the main body.

As a result of this kind of configuration in which a lead is fixed to a connecting portion and an extended leading end of the lead is caused to oppose the connecting portion, a process of bending the lead, and the like, is unnecessary, and manufacture of an electronic part, and by extension a semiconductor storage device, can be simplified. Furthermore, as the lead is fixed to the connecting portion without being bent, an inclination of the electronic part caused by a variation in bending of the lead does not occur. Consequently, a required level of processing technology and processing accuracy of the semiconductor storage device can be lowered.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
a substrate having a connecting portion;
a semiconductor memory provided on the substrate; and
an electronic part that has a main body that is disposed in the substrate, and a lead extending from the main body, wherein
a central axial line of the main body is aligned with a center of the substrate in a thickness direction of the substrate, and
the lead extends linearly and has a leading end that is fixed to the connecting portion and aligned with the connecting portion in a direction along which the lead extends from the main body.

2. The semiconductor storage device according to claim 1, wherein the electronic part is a storage part having a cylindrical external form.

3. The semiconductor storage device according to claim 2, wherein the lead extends parallel to the central axial line of the main body from an end face of the main body.

4. The semiconductor storage device according to claim 3, wherein the electronic part further includes another lead extending parallel to the central axial line of the main body from the end face of the main body.

5. The semiconductor storage device according to claim 1, wherein the connecting portion comprises an end face through hole that is formed at an edge portion of the substrate that is cut out.

6. The semiconductor storage device according to claim 5, wherein the substrate has an aperture and the edge portion of the substrate faces the aperture.

7. The semiconductor storage device according to claim 5, wherein the connecting portion includes an inner cover portion, which covers an inner side of the edge portion of the substrate that is cut out, a first flange portion connected to a first end portion of the inner cover portion in the thickness direction of the substrate and extend along a front face of the substrate, and a second flange portion connected to a second end portion of the inner cover portion in the thickness direction of the substrate and extend along a back face of the substrate, and
an anchor that is provided on at least one of the pair of flange portions and fixes the connecting portion to the substrate.

8. The semiconductor storage device according to claim 1, wherein the lead is embedded in solder to be electrically connected to and mechanically fixed to the connecting portion.

9. The semiconductor storage device according to claim 8, wherein the lead is completely embedded in the solder except where the lead extends from the main body into the solder.

10. A semiconductor storage device, comprising:
a substrate having a first face, which extends in a first direction and a second direction perpendicular to the first direction, a second face, which is positioned on a side opposite to that of the first face, and a third face, wherein the third face extends from the first face to the second face in a third direction that is perpendicular to the first and second directions and is a thickness direction of the substrate, and has a connecting portion;
a semiconductor memory provided on the first face; and
an electronic part having a main body and a first lead that extends in the first direction from the main body, wherein
a center in the third direction of the main body overlaps the third face when viewed along the first direction, and
a leading end of the first lead is fixed to the connecting portion to face the connecting portion in the first direction.

11. The semiconductor storage device according to claim 10, wherein the electronic part is a storage part having a cylindrical external form.

12. The semiconductor storage device according to claim 10, wherein
the electronic part further has a second lead that extends in the first direction from the main body, and
a leading end of the second lead is fixed to the connecting portion to face the connecting portion in the first direction.

13. The semiconductor storage device according to claim 12, wherein
the main body has an end face facing the third face, and
the first lead and the second lead extend linearly from the end face toward the third face.

14. The semiconductor storage device according to claim 13, wherein the first lead and the second lead extend linearly along a direction that is parallel to a central axis of the main body.

15. A method of manufacturing a semiconductor storage device including a substrate, a semiconductor memory provided on the substrate, and an electronic part having a main body and a lead extending linearly from the main body, said method comprising:
disposing the electronic part in an aperture formed through the substrate to align a central axial line of the main body with a center of the substrate in a thickness direction of the substrate;
positioning a leading end of the lead to face a connecting portion formed on a side face of the substrate in a direction along which the lead extends from the main body; and
fixing the lead to the connecting portion while the leading end of the lead is facing the connecting portion in the direction along which the lead extends from the main body.

16. The method according to claim 15, wherein the lead is fixed to the connecting portion by a solder that also electrically connects the lead to the connecting portion.

17. The method according to claim 16, wherein the lead is completely embedded in the solder except where the lead extends from the main body into the solder.

18. The method according to claim 15, further comprising:
anchoring the connection portion to the substrate.

19. The method according to claim 15, further comprising:
disposing a plurality of other electronic parts in the aperture formed through the substrate, each of the other electronic parts including a lead; and
fixing the lead of each of the other electronic parts to a corresponding connecting portion formed on the side face of the substrate.

20. The method according to claim 15, wherein the electronic part is a capacitor having a cylindrical external form.
